(19) United States
(12) Patent Application Publication
(10) Pub. No.: US 2013/0076405 A1
(43) Pub. Date: Mar. 28, 2013

(54) SYSTEMS AND METHODS FOR DISCHARGING BUS VOLTAGE USING SEMICONDUCTOR DEVICES

(71) Applicants: RAY M. RANSOM, BIG BEAR CITY, CA (US); DAVID TANG, RANCHO CUCAMONGA, CA (US)

(72) Inventors: RAY M. RANSOM, BIG BEAR CITY, CA (US); DAVID TANG, RANCHO CUCAMONGA, CA (US)

(73) Assignee: GM GLOBAL TECHNOLOGY OPERATIONS LLC, DETROIT, MI (US)

(21) Appl. No.: 13/243,990

(22) Filed: Sep. 23, 2011

(51) Int. Cl. H03K 3/01

(52) U.S. Cl. 327/109

(57) ABSTRACT

Systems, apparatus, and methods are provided for discharging a voltage bus using a transistor. An exemplary gate drive circuit associated with the transistor includes a pulse generation module having an input and an output and a switched capacitance arrangement coupled between the output and a reference voltage node. The pulse generation module is configured to generate a voltage pulse at its output in response to a control signal at the input. In one embodiment, the control signal results in the voltage pulse having a duty cycle that operates the transistor associated with the gate drive circuit in a linear mode when the switched capacitance arrangement is activated.

### TECHNICAL FIELD

Embodiments of the subject matter described herein relate generally to electrical systems, and more particularly, embodiments of the subject matter relate to discharging a high-voltage bus in electric and hybrid vehicles.

### BACKGROUND

In recent years, advances in technology have led to substantial changes in the design of automobiles. In hybrid and/or electric vehicles, energy storage devices, such as capacitors, are often used to improve efficiency and/or capture energy within the powertrain system. However, capacitors may retain a charge after power is removed from a circuit or an automobile is turned off. Therefore, high-voltage capacitors should be properly discharged after turning off a vehicle and/or before the equipment housing the capacitors is accessed.

Discharging a capacitor is traditionally accomplished by placing a discharge or bleed resistor across the capacitor or bus terminals in parallel. In addition to requiring additional components, these designs also require discharge resistors with the ability to handle high average power dissipation. These resistors generally occupy a larger surface area and often require additional harnesses, connectors, and heat sinks, which prevent the discharge resistors from being built on a circuit board. In addition to the increased spatial requirements, these discharge circuits are not utilized during normal operating modes.

### BRIEF SUMMARY

In accordance with one embodiment, a gate drive circuit is provided. The gate drive circuit includes a pulse generation module having an input and an output and a switched capacitance arrangement coupled between the output and a reference voltage node. The pulse generation module is configured to generate a voltage pulse at the output in response to a control signal at the input. In one embodiment, the duty cycle of the voltage pulse is chosen to operate a transistor associated with the gate drive circuit in a linear mode when the switched capacitance arrangement is activated.

In accordance with another embodiment, an electrical system suitable for use in a vehicle is provided. The electrical system includes a first voltage rail, a second voltage rail, a transistor coupled between the first voltage rail and the second voltage rail, gate drive circuitry, and a control module coupled to the gate drive circuitry. The gate drive circuitry includes a first node coupled to a control terminal of the transistor, a pulse generation module configured to generate a voltage pulse at its output, and a switched capacitance arrangement coupled between the first node and a reference voltage node, wherein the first node is coupled to the output of the pulse generation module. The control module is configured to activate the switched capacitance arrangement in response to a discharge condition.

In another embodiment, a method is provided for discharging an energy potential between a first node and a second node using a transistor coupled between the first node and the second node. The method involves identifying a discharge condition and activating a switched capacitance arrangement coupled between a reference voltage node and a third node in response to identifying the discharge condition. The third node is coupled to a control terminal of the transistor. After activating the switched capacitance arrangement, the method continues by providing one or more voltage pulses to the third node after activating the switched capacitance arrangement to operate the transistor in a linear mode.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a block diagram of an electrical system suitable for use in a vehicle in accordance with one embodiment;

FIG. 2 is a schematic view of an exemplary gate drive circuit suitable for use in the electrical system of FIG. 1 in accordance with one embodiment; and

FIG. 3 is a flow diagram of control process suitable for use with the gate drive circuitry of FIG. 2 in the electrical system of FIG. 1 in accordance with one embodiment.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

Embodiments of the subject matter described herein relate generally to systems and methods for discharging high-voltages that exist in electrical systems, such as, for example, electric and hybrid vehicle drive systems. As described in greater detail below, in an exemplary embodiment, the gate drive circuit for at least one transistor of a power inverter (alternatively referred to herein as a discharge transistor) includes a switched capacitance that is capable of being selectively provided between the control (or gate) terminal of the transistor and a reference voltage node. In this regard, to discharge the voltage bus coupled to the power inverter, the switched capacitance is activated such that it is effectively coupled between the gate terminal of the discharge transistor and the reference voltage. By virtue of this capacitance, pulse-width modulated voltage pulses that would normally be provided to the gate terminal are filtered, such that the discharge transistor is operated in a linear mode, as opposed to a saturation mode. The other transistor of the inverter phase leg is turned on, and the discharge transistor effectively provides a resistance that dissipates the bus voltage.

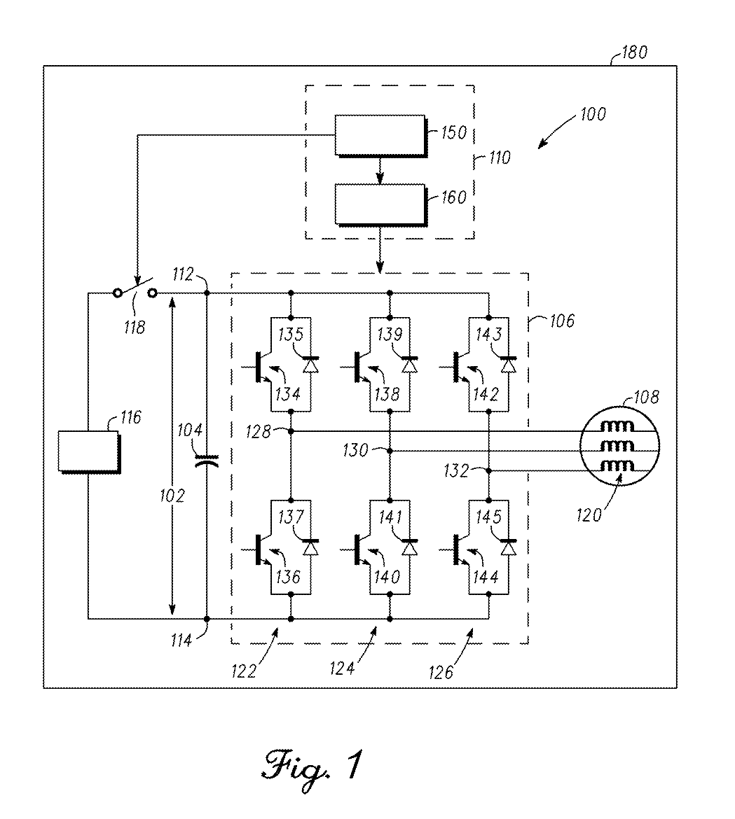

FIG. 1 illustrates an exemplary embodiment of an electrical system 100 suitable for use in an automotive vehicle 180. The electrical system 100 includes, without limitation, a voltage bus 102, a capacitive element 104, an inverter module 106, a motor 108, and a control system 110. The inverter module 106 is coupled between the bus 102 and the motor 108, and the inverter module 106 provides AC power to the motor 108 from the bus 102 under control of the control system 110, as described in greater detail below. It should be understood that FIG. 1 is a simplified representation of the electrical system 100 for purposes of explanation and ease of description, and FIG. 1 is not intended to limit the scope or applicability of the subject matter described herein in any way. Thus, although FIG. 1 depicts direct electrical connections between circuit elements and/or terminals, alternative embodiments may employ intervening circuit elements and/or components while functioning in a substantially similar manner. Furthermore, although FIG. 1 illustrates an embodiment where the inverter module 106 and the motor 108 each have three-phases, it should be understood that the principles and subject matter described herein applies to an electrical system with any number of phases and may be modified accordingly, as will be appreciated in the art. Thus, although the subject matter may be described herein in the context of a three-phase implementation, the subject matter is not limited to three-phase applications and may be utilized with inverters and/or motors having any number of phases.

In an exemplary embodiment, the bus 102 includes a pair of conductive elements, such as wires, cables, or busbars. In this regard, a first conductive element 112 of the bus 102 corresponds to a positive voltage and a second conductive element 114 corresponds to a negative voltage, wherein the difference between the positive voltage and the negative voltage is considered to be the voltage of the bus 102 (or alternatively, the bus voltage). Accordingly, for convenience, but without limitation, the first conductive element 112 may be referred to herein as the positive rail of the bus 102 and the second conductive element 114 may be referred to herein as the negative rail of the bus 102. In an exemplary automotive embodiment, the bus 102 functions as a high-voltage bus with a bus voltage that may range from about 300 volts to about 500 volts or higher during normal operation of the vehicle 180.

In the illustrated embodiment of FIG. 1, the bus 102 is coupled to a direct current (DC) energy source 116 (e.g., a battery or battery pack, a fuel cell or fuel cell stack, a DC/DC converter output, or the like) via a suitably configured switching arrangement 118 (e.g., a contactor, relay, or the like). When the switching arrangement 118 is closed or otherwise activated, the DC energy source 116 provides DC voltage/current to the bus 102 which is converted to AC power by the inverter module 106 and provided to the motor 108. As illustrated, a capacitive element 104, such as a capacitor, is connected between the positive rail 112 and the negative rail 114 of the bus 102 and interposed between the DC energy source 116 and the input of the inverter module 106 to capture energy within the electrical system 100 or otherwise reduce voltage ripple on the bus 102. As described in greater detail below, in an exemplary embodiment, the control system 110 opens or otherwise deactivates the switching arrangement 118 in response to a discharge condition to decouple the energy source and allow voltage stored on the capacitor 104 and/or elsewhere within the electrical system 100 to be discharged from the bus 102.

In an exemplary embodiment, the motor 108 is realized as an electric motor, and depending on the embodiment, may be an induction motor, a permanent magnet motor, or another type of motor suitable for the desired application. Although not illustrated, the motor 108 may also include a transmission integrated therein such that the motor and the transmission are mechanically coupled to the drive shaft of the vehicle 180 to provide traction power to the vehicle 180. As illustrated in FIG. 1, in an exemplary embodiment, the motor 108 is realized as a multi-phase alternating current (AC) motor that includes a set of windings 120 (or coils), wherein each winding corresponds to a respective phase of the motor 108.

In an exemplary embodiment, the inverter module 106 includes a power inverter having one or more phase legs 122, 124, 126, wherein each inverter phase leg 122, 124, 126 is coupled between the positive rail 112 and the negative rail 114 of the bus 102. Each inverter phase leg 122, 124, 126 includes a pair of switching elements, with each switching element having a freewheeling diode associated therewith, and a respective output node 128, 130, 132 between sets of switches and diodes, as illustrated in FIG. 1. The output nodes 128, 130, 132 of the inverter phase legs are each electrically connected to a corresponding phase (or winding 120) of the motor 108. In an exemplary embodiment, during normal motoring operation when the switching arrangement 118 is closed, the control system 110 provides pulse-width modulated (PWM) signals to operate (i.e., open and close) the switches of the phase legs 122, 124, 126 with desired timing and duty cycles to convert DC voltage from the bus 102 into a desired AC voltage at the output nodes 128, 130, 132. The output nodes 128, 130, 132 are coupled to windings 120 to provide the AC voltage across the windings 120 and thereby operate the motor 108 to provide traction power to the vehicle 180.

As described above, each phase leg 122, 124, 126 of the inverter module 106 includes a pair of switching elements 134, 136, 138, 140, 142, 144 with a freewheeling diode 135, 137, 139, 141, 143, 145 coupled antiparallel to each switching element. The switching elements 134, 136, 138, 140, 142, 144 and diodes 135, 137, 139, 141, 143, 145 are antiparallel, meaning they are electrically in parallel with reversed or inverse polarity. The antiparallel configuration allows for bidirectional current flow while blocking voltage unidirectionally, as will be appreciated in the art. In this configuration, the direction of current through the switching elements 134, 136, 138, 140, 142, 144 is opposite to the direction of allowable current through the respective diodes 135, 137, 139, 141, 143, 145. In an exemplary embodiment, the switching elements 134, 136, 138, 140, 142, 144 are realized as transistors, such as insulated gate bipolar transistors (IGBTs), field-effect transistors (e.g., MOSFETs), or another suitable semiconductor switching device. For convenience, but without limitation, the switching elements 134, 136, 138, 140, 142, 144 are alternatively referred to herein as transistors, and the control terminal of a respective switching element 134, 136, 138, 140, 142, 144 may alternatively be referred to herein as a gate terminal without limiting the switching elements 134, 136, 138, 140, 142, 144 to any particular transistor technology or semiconductor switching device.

In the illustrated embodiment of FIG. 1, a first phase leg 122 includes a first set of a transistor 134 and diode 135 connected between the positive rail 112 and its output node 128 and a second set of a transistor 136 and diode 137 connected between its output node 128 and the negative rail 114, wherein the first transistor 134 is configured to allow current from the positive rail 112 to the output node 128 and the second transistor 136 is configured to allow current from the output node 128 to the negative rail 114. Similarly, a second phase leg 124 includes a transistor 138 and diode 139 connected between the positive rail 112 and output node 130 and another transistor 140 and diode 141 connected between output node 130 and the negative rail 114, and a third phase leg 126 includes a transistor 142 and diode 143 connected between the positive rail 112 and output node 132 and another transistor 144 and diode 145 connected between output node 132 and the negative rail 114. For convenience, a transistor 134, 138, 142 coupled to the positive rail 112 may alternatively be referred to herein as a positive transistor and a transistor 136, 140, 144 coupled to the negative rail 114 may alternatively be referred to herein collectively as a negative transistor).

As described in greater detail below, in an exemplary embodiment, one of the negative transistors 136, 140, 144 is functions as a discharge transistor that is operated in a linear mode to discharge the voltage bus 102. For purposes of explanation, but without limitation, the subject matter is described herein in the context of the negative transistor 136 of the first inverter phase leg 122 functioning as the discharge transistor in the electrical system 100. However, it should be noted that in practice, more than one of the negative transistors 136, 140, 144 may function as a discharge transistor, or that the subject matter may be implemented in an equivalent manner to utilize one of the positive transistors 134, 138, 142 as a discharge transistor.

Still referring to FIG. 1, the control system 110 generally represents the hardware, firmware, software and/or other components (or a combination thereof) configured to modulate (open and/or close) the transistors of the inverter module 106 to deliver energy to the motor 108. In an exemplary embodiment, the control system 110 includes a control module 150 and gate drive circuitry 160. The control module 150 generally represents the hardware, firmware and/or software (or a combination thereof) configured to achieve a desired power flow between the voltage bus 102 and the motor 108. For example, the control module 150 may receive an input torque command for operating the electric motor 108 and determine and/or generate PWM control signals to modify the duty cycles and/or timing for the transistors of the inverter phase legs 122, 124, 126 to control the voltage at the output nodes 128, 130, 132 and produce the commanded torque in the electric motor 108. Depending on the embodiment, the control module 150 may be implemented or realized with a general purpose processor, a microprocessor, a microcontroller, a content addressable memory, a digital signal processor, an application specific integrated circuit, a field programmable gate array, any suitable programmable logic device, discrete gate or transistor logic, discrete hardware components, or any combination thereof, designed to support operation of the electrical system 100 and/or perform the functions described herein.

In the embodiment of FIG. 1, the gate drive circuitry 160 generally represents the hardware (e.g., amplifiers, current buffers, voltage level translation circuitry, opto-isolators, gate drivers, and the like) configured to employ high frequency pulse-width modulation (PWM) to modulate (turn on and/or turn off) the transistors of the inverter module 106 in response to PWM control signals received from the control module 150. In this regard, the gate drive circuitry 160 is coupled to the control (or gate) terminal of each of the transistors 134, 136, 138, 140, 142, 144 and is configured to provide voltage pulses to the control terminals of the various transistors 134, 136, 138, 140, 142, 144 in response to the PWM control signals received from the control module 150.

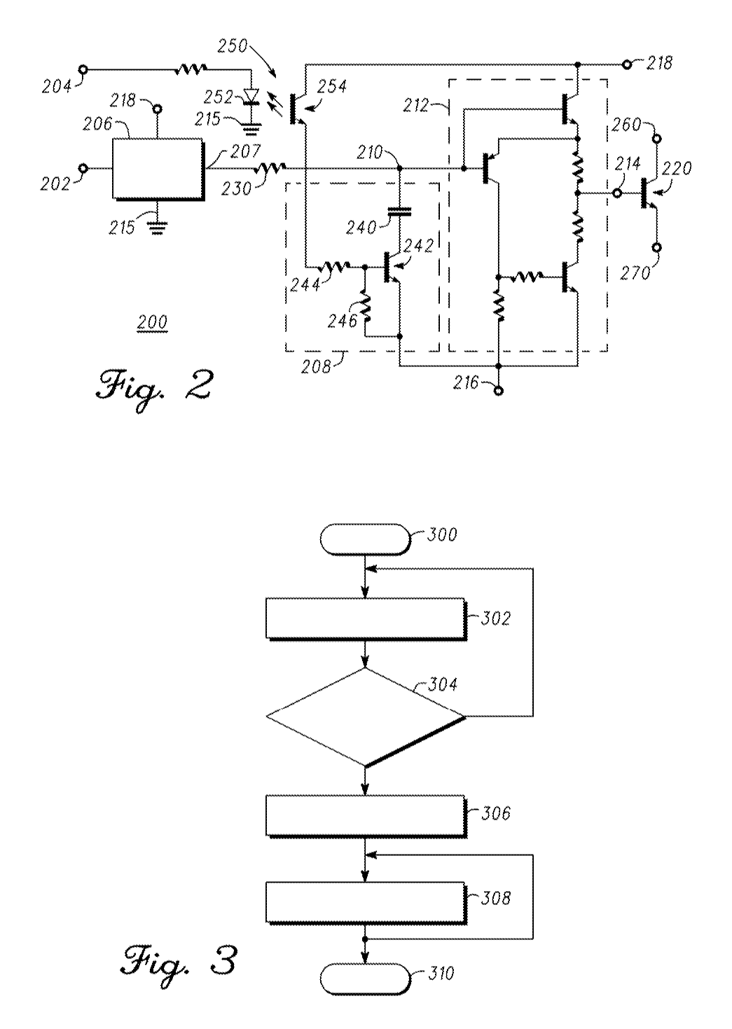

As described in greater detail below in the context of FIGS. 2-3, in an exemplary embodiment, the gate drive circuitry 160 includes, for the discharge transistor 136 in the inverter module 106, a switched capacitance that is capable of being selectively provided between the control terminal of the discharge transistor 136 and a reference voltage node. The control module 150 and/or control system 110 is configured to detect a discharge condition and in response to detecting a discharge condition, open or otherwise deactivate the switching element 118 and signal the gate drive circuitry 160 to activate the switched capacitance such that the switched capacitance is effectively electrically connected between the control terminal of the discharge transistor 136 and the reference voltage node. As used herein, a discharge condition should be understood as a situation where it is desirable to discharge a voltage that may be stored within an electrical system (e.g., by capacitor 104 or another element coupled to the bus 102) to protect against electrostatic discharge or other negative effects. For example, a discharge condition may be an attempt to access a unit or compartment containing a high-voltage component, a vehicle crash or accident, or turning off of a vehicle housing the electrical system. Although not illustrated, the control module 150 and/or control system 110 may be configured to detect the discharge condition using one or more sensors or receive an input signal indicative of a discharge condition from another vehicle module, such as an electronic control unit.

Still referring to FIG. 1, after activating the switched capacitance for the discharge transistor 136, in an exemplary embodiment, the control module 150 activates or otherwise turns on the other transistor 134 of the inverter phase leg 122 including the discharge transistor 136 and sets the duty cycle for the discharge transistor 136 to a percentage of the PWM switching cycle that results in that discharge transistor 136 operating in a linear mode while the other transistor 134 of the inverter phase leg 122 is turned on to discharge the voltage bus 102.

FIG. 2 depicts an exemplary gate drive circuit 200 suitable for use in the gate drive circuitry 160 in the electrical system 100 of FIG. 1. In an exemplary embodiment, the gate drive circuit 200 is used with the discharge transistor 220 in an inverter phase leg (e.g., transistor 136 of inverter phase leg 122) to facilitate operating the discharge transistor 220 in a linear mode in response to a discharge condition. The gate drive circuit 200 includes, without limitation, a control input node 202 for receiving a PWM duty cycle control signal, a discharge input node 204 for receiving a discharge signal, a pulse generation module 206, a switched capacitance arrangement 208 coupled to the output 207 of the pulse generation module 206 at node 210, and an amplifier arrangement 212 coupled between node 210 and an output node 214. As described in greater detail below, in an exemplary embodiment, the output node 214 of the gate drive circuit 200 is connected to the gate terminal of the discharge transistor 220 of an inverter phase leg (e.g., transistor 136 of inverter phase leg 122) to provide PWM voltage pulses to the gate terminal of the discharge transistor 220.

In an exemplary embodiment, the pulse generation module 206 generally represents the hardware, firmware, software and/or other components (or a combination thereof) configured to receive PWM duty cycle control signals at the control input node 202 (e.g., from control module 150) and generate corresponding voltage pulses having those duty cycles at its output. In this regard, the pulse generation module 206 is coupled to a ground reference voltage node 215 for the gate drive circuit 200 and a positive (or supply) reference voltage node 218 for the gate drive circuit 200, wherein the voltage pulses provided at the output 207 alternate between a voltage substantially equal to the positive reference voltage at node 218 for a percentage of a PWM switching cycle and a voltage substantially equal to the ground reference voltage at node 215 for the remainder of the PWM switching cycle, with the percentages of the PWM switching cycle being indicated by the PWM duty cycle control signals at the control input node 202. In an exemplary embodiment, a resistive element 230, such as a resistor, is connected in series between the output 207 of the pulse generation module 206 and node 210. The amplifier arrangement 212 is coupled between the output of the pulse generation module 206 at node 210 and the output node 214, and the amplifier arrangement 212 is realized as a current amplifier that translates the voltage level at node 210 to an output voltage at a higher current level suitable for operating the discharge transistor 220 of the inverter phase leg.

Still referring to FIG. 2, in the illustrated embodiment, the switched capacitance arrangement 208 includes a capacitive element 240 and a switching element 242 coupled between the output 207 of the pulse generation module 206 at node 210 and a negative reference voltage node 216 for the gate drive circuit 200. The capacitive element 240 and the switching element 242 are configured in electrically series between the nodes 210, 216, such the switching element 242 controls current flowing to/from the capacitive element 240 and that any current flowing to/from the capacitive element 240 flows through the switching element 242 when the switching element 242 is activated, closed, or otherwise turned on.

In the illustrated embodiment of FIG. 2, the switching element 242 is realized as a bipolar junction transistor having an emitter terminal coupled to the negative reference voltage node 216 and a collector terminal coupled to one terminal of the capacitive element 240, wherein the other terminal of the capacitive element 240 is coupled to the output 207 of the pulse generation module 206 at node 210. The gate (or base) terminal of the transistor 242 is coupled to the discharge input node 204 via an isolation switching element 250, such as an optocoupler (or opto-isolator). The illustrated optocoupler 250 includes a light-emitting diode 252 (or another light source) and a corresponding photosensor 254 (a phototransistor, a photoresistor, or the like). The anode terminal of the light-emitting diode 252 is coupled to the discharge input node 204, the cathode terminal of the light-emitting diode 252 is coupled to the ground reference voltage node 215, and the photosensor 254 is coupled between the gate terminal of the transistor 242 and the positive reference voltage node 218 such that in response to a discharge signal at the discharge input node 204 (e.g., a logical high voltage at the discharge input node 204), the optocoupler 250 is activated or otherwise turned on to allow current to flow from the positive reference voltage node 218 to the gate terminal of the transistor 242 and/or negative reference voltage node 216. In an exemplary embodiment, the switched capacitance arrangement 208 includes a pair of resistive elements 244, 246 coupled between the optocoupler 250, the negative reference voltage node 216, and the gate terminal of the transistor 242 and configured as a voltage divider, such that the increase in current through the optocoupler 250 causes the voltage at the gate terminal of the transistor 242 to increase above the threshold voltage of the transistor 242, thereby turning on or otherwise activating the transistor 242. In this manner, the discharge signal at the discharge input node 204 activates or otherwise turns on the switched capacitance arrangement 208 (e.g., by activating or turning on transistor 242), resulting in the capacitive element 240 being effectively connected between the gate terminal of the discharge transistor 220 and/or the output 207 of the pulse generation module 206 at node 210 and the negative reference voltage node 216.

It should be noted that although FIG. 2 depicts the switching element 242 as being realized as a bipolar junction transistor with an isolation switching element 250 and voltage divider arrangement (resistors 244, 246) suitably configured to activate and/or deactivate the switching element 242, the switching element 242 is not intended to be limited to any particular type of transistor and/or switching arrangement. For example, in alternative embodiments, the switching element 242 may be realized as another type of transistor (e.g., a field effect transistor). Furthermore, in some embodiments, the isolation switching element 250 may be used in lieu of switching element 242 and resistors 244, 246. For example, the photosensor 254 of the octocoupler 250 may be connected between the capacitive element 240 and the negative reference voltage node 216 such that in response to a discharge signal at the discharge input node 204, the optocoupler 250 is activated or otherwise turned on to allow current to flow to/from the capacitive element 240, thereby activating the switched capacitance arrangement 208 such that the capacitive element 240 is effectively connected between node 210 and the negative reference voltage node 216 via the octocoupler 250.

When the switched capacitance arrangement 208 is activated, the capacitance of the capacitive element 240 and the resistance of the resistive element 230 effectively create a low-pass (or RC) filter between the output 207 of the pulse generation module 206 and the gate terminal of the discharge transistor 220 (e.g., via the amplifier arrangement 212). As described in greater detail below, the low-pass filtering of the voltage pulses provided at the output 207 of the pulse generation module 206 results in an output voltage at the output node 214 that causes the discharge transistor 220 to be operated in a linear mode to discharge any voltage differential between a first node 260 (e.g., phase leg output node 128 and/or positive voltage rail 112) and a second node 270 (e.g., negative voltage rail 114).

It should be understood that FIG. 2 is a simplified representation of the gate drive circuit 200 for purposes of explanation and ease of description, and FIG. 2 is not intended to limit the scope or applicability of the subject matter described herein in any way. Thus, although FIG. 2 depicts direct electrical connections between circuit elements and/or terminals, alternative embodiments may employ intervening circuit elements and/or components while functioning in a substantially similar manner. Additionally, although FIG. 2 depicts the switched capacitance arrangement 208 being coupled between the input of the amplifier arrangement 212 (e.g., node 210) and the negative reference voltage node 216, in other embodiments, the switched capacitance arrangement 208 may be coupled between the gate terminal of the discharge transistor 220 and/or the output node 214. In this regard, the amplifier arrangement 212 may be implemented within the pulse generation module 206 or otherwise precede the switched capacitance arrangement 208, and in some embodiments, the amplifier arrangement 212 may be left out entirely.

Referring now to FIG. 3, in an exemplary embodiment, an electrical system may be configured to perform a control process 300 and additional tasks, functions, and operations described below. The various tasks may be performed by software, hardware, firmware, or any combination thereof. For illustrative purposes, the following description may refer to elements mentioned above in connection with FIG. 1 or FIG. 2. In practice, the tasks, functions, and operations may be performed by different elements of the described system, such as the inverter module 106, the control system 110, the control module 150, the gate drive circuitry 160, 200, and/or the pulse generation module 206. It should be appreciated that any number of additional or alternative tasks may be included, and may be incorporated into a more comprehensive procedure or process having additional functionality not described in detail herein.

Referring to FIG. 3, and with continued reference to FIG. 1 and FIG. 2, a control process 300 may be performed to discharge a voltage bus (e.g., bus 102) without requiring additional hardware components dedicated to discharging the voltage. In an exemplary embodiment, the control process 300 begins by operating an inverter module to deliver power (or current) to/from a motor in the vehicle (task 302). In this regard, the control module 150 determines or otherwise generates PWM duty cycle control signals that control the duty cycles of the transistors of the inverter module 106 (i.e., the amount of time a respective transistor is turned on or activated) as well as the timing for operating the transistors (i.e., the time when a transistor is turned on or turned off). The control module 150 provides the PWM duty cycle control signals to the gate drive circuitry 160 (e.g., at control input node 202 of gate drive circuit 200) such that in response to the PWM duty cycle control signals from the control module 150, the gate drive circuitry 160, 200 and/or pulse generation module 206 produces PWM voltage pulses that operate the transistors of the inverter module 106 with the appropriate duty cycles and timing to achieve a desired power flow to/from the motor 108. During normal operation, the control module 150 provides a logical low voltage at the discharge input node 204 of the gate drive circuit 200 to deactivate or otherwise disable the switched capacitance arrangement 208 that is coupled to the gate terminal of the discharge transistor 136, 220.

In an exemplary embodiment, the control process 300 continues by determining whether a discharge condition exists or has occurred (task 304). In this regard, the control system 110 and/or control module 150 monitors the electrical system 100 for a situation where it is desirable to discharge a voltage on the bus 102 or otherwise stored by the capacitor 104, as described above. In response to detecting or otherwise identifying the discharge condition, the control system 110 and/or control module 150 opens, turns off, or otherwise deactivates the switching arrangement 118 to decouple the energy source 116 from the voltage bus 102.

In an exemplary embodiment, after detecting or otherwise identifying a discharge condition, the control process 300 continues by activating the switched capacitance coupled the control terminal of one or more discharge transistors in the inverter module (task 306). In this regard, for a discharge transistor 136, 220 in the inverter module 106 having a switched capacitance coupled to its gate terminal (e.g., capacitive element 240), the inverter module 106 activates the switched capacitance such that the switched capacitance is effectively connected between the gate terminal of the discharge transistor 136, 220 and a reference voltage node. For example, for discharge transistor 136, 220 in inverter phase leg 122, the control module 150 provides a discharge signal (e.g., a logical high voltage) to the discharge input node 204 of the gate drive circuit 200 for that transistor 136, 220. In response to the logical high discharge signal, the optocoupler 250 is activated or otherwise turned on to activate the switched capacitance arrangement 208 and provide the capacitance of the capacitive element 240 between the negative reference voltage node 216 and the node 210 that is coupled to the gate terminal of the discharge transistor 136, 220 (e.g., via amplifier arrangement 212).

After activating the switched capacitance for one or more discharge transistors of the inverter module, the control process 300 continues by operating the inverter module to discharge the voltage bus (task 308). In this regard, for the inverter phase leg 122 that includes a discharge transistor 136, the control system 110 and/or control module 150 turns on or otherwise activates the other transistor 134 of that inverter phase leg 122 (e.g., by providing PWM duty cycle control signals corresponding to a PWM duty cycle of 100% to the gate drive circuitry 160 associated with that transistor 134), such that the discharge transistor 136 is effectively connected between the two voltage rails 112, 114 of the voltage bus 102 (e.g., by effectively tying the phase leg output node 128 to the positive voltage rail 112). For the discharge transistor 136, the control system 110 and/or control module 150 provides PWM duty cycle control signals to the pulse generation module 206 of its associated gate drive circuitry 160, 200, wherein the PWM duty cycle control signals correspond to a duty cycle that is configured to operate the discharge transistor 136, 220 in a linear mode. In this regard, the duty cycle is configured such that after the voltage pulses generated by the pulse generation module 206 at its output 207 are filtered by the resistive element 230 and capacitive element 240, the voltage at the output node 214 that is applied to the gate terminal of the discharge transistor 136, 220 does not meet or exceed an upper threshold voltage that would result in the discharge transistor 136, 220 being fully turned on and operating in a saturation mode. In other words, for at least a portion of the PWM cycle (or switching interval), the output voltage at the output node 214 is greater than a lower threshold voltage that causes the discharge transistor 136, 220 to conduct current from node 260 (e.g., positive voltage rail 112 and/or phase leg output node 128) to node 270 (e.g., negative voltage rail 114) while at the same time being less than the upper threshold voltage that would otherwise cause the discharge transistor 136, 220 to operate in the saturation region. Thus, the discharge transistor 136, 220 provides an effective resistance between nodes 260, 270 (e.g., between the negative rail 114 and the inverter output node 128 and/or positive rail 112) to discharge any voltage differential between nodes 260, 270.

In an exemplary embodiment, the control process 300 continues operating the discharge transistor(s) of the inverter module until the bus voltage is less than a threshold value. In this regard, the control system 110 and/or control module 150 may maintain transistor 134 turned on or activated while continuing to provide PWM duty cycle command signals configured to operate the discharge transistor 136, 220 in the linear mode until the voltage difference between the voltage rails 112, 114 of the voltage bus 102 is less than a threshold voltage. For example, the control system 110 and/or control module 150 may operate the discharge transistor 136, 220 in the linear mode until the bus voltage is less than or equal to a threshold voltage in the range of about 30 Volts to about 50 Volts.

In accordance with one or more embodiments, after the bus voltage is less than or equal to a threshold voltage, the control system 110 and/or control module 150 may terminate the control process 300 by deactivating the switched capacitance arrangement 208 for the discharge transistor 136, 220 (e.g., by providing a logical low voltage signal to the discharge input node 204) and turning off or otherwise deactivating the transistors 134, 136 of the inverter phase leg 122 (e.g., by providing PWM duty cycle control signals corresponding to duty cycles of 0% for transistors 134, 136 to the gate drive circuitry 160, 200) after the bus voltage is less than the threshold value (task 310). It should be noted that while operating the discharge transistor 136 and/or discharge phase leg 122 of the inverter module 106 to discharge the voltage bus 102, the control system 110 and/or control module 150 may turn off or otherwise deactivate the transistors 138, 140, 142, 144 of the remaining phase legs 124, 126 of the inverter module 106 (e.g., by providing PWM duty cycle control signals corresponding to duty cycles of 0% for those transistors to the gate drive circuitry 160) to prevent production of torque in the motor 108.

To briefly summarize, advantages of the subject matter described herein is that a high-voltage bus may be discharged without requiring additional discharge components, such as discharge resistors or relays. Furthermore, the bus may be discharged in a manner that allows for a fast discharge of the bus while also minimizing the power absorption or stress on the semiconductor devices. It should be noted that the subject matter described above is not limited to use in automotive vehicles, and may be utilized in different vehicles (e.g., watercraft and aircraft) or in other electrical systems altogether, as it may be implemented in any situation where a voltage needs to be reliably discharged.

For the sake of brevity, conventional techniques related to electrical energy and/or power conversion, transistor-based switch control, PWM, automotive drive systems and/or electric motor drive systems, and other functional aspects of the systems (and the individual operating components of the systems) may not be described in detail herein. Furthermore, the connecting lines shown in the various figures contained herein are intended to represent exemplary functional relationships and/or physical couplings between the various elements. It should be noted that many alternative or additional functional relationships or physical connections may be present in an embodiment of the subject matter.

As used herein, a “node” means any internal or external reference point, connection point, junction, signal line, conductive element, or the like, at which a given signal, logic level, voltage, data pattern, current, or quantity is present. Furthermore, two or more nodes may be realized by one physical element (and two or more signals can be multiplexed, modulated, or otherwise distinguished even though received or output at a common node).

The foregoing description refers to elements or nodes or features being “connected” or “coupled” together. As used herein, unless expressly stated otherwise, “connected” means that one element/node/feature is directly joined to (or directly communicates with) another element/node/feature, and not necessarily mechanically. Likewise, unless expressly stated otherwise, “coupled” means that one element/node/feature is directly or indirectly joined to (or directly or indirectly communicates with) another element/node/feature, and not necessarily mechanically. Thus, although the figures may depict one exemplary arrangement of elements, additional intervening elements, devices, features, or components may be present in an embodiment of the depicted subject matter. In addition, certain terminology may also be used herein for the purpose of reference only, and thus is not intended to be limiting. For example, the terms “first”, “second” and other such numerical terms referring to structures do not imply a sequence or order unless clearly indicated by the context.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A gate drive circuit comprising:
a pulse generation module having an input and an output, the pulse generation module being configured to generate a voltage pulse at the output in response to a control signal at the input; and
a switched capacitance arrangement coupled between the output and a reference voltage node.

2. The gate drive circuit of claim 1, wherein:
the output is coupled to a control terminal of a transistor at a first node; and
the switched capacitance arrangement provides a capacitance between the first node and the reference voltage node when the switched capacitance arrangement is activated.

3. The gate drive circuit of claim 2, wherein the pulse generation module generates the voltage pulse with a duty cycle that operates the transistor in a linear mode.

4. The gate drive circuit of claim 1, wherein the switched capacitance arrangement comprises:
a capacitive element; and
a switching element, wherein the capacitive element and the switching element are coupled electrically in series between the reference voltage node and a first node, the first node being coupled to the output of the pulse generation module.

5. The gate drive circuit of claim 4, further comprising a resistive element coupled electrically in series between the output of the pulse generation module and the first node.

6. The gate drive circuit of claim 4, further comprising a second node configured to receive a discharge signal, the second node being coupled to the switching element, wherein the switching element is activated in response to the discharge signal.

7. The gate drive circuit of claim 6, wherein the switching element comprises a transistor having a control terminal coupled to the second node.

8. The gate drive circuit of claim 7, further comprising an isolation element coupled between the second node and the control terminal of the transistor, wherein the isolation element is configured to turn on the transistor in response to the discharge signal.

9. An electrical system comprising:
a first voltage rail;
a second voltage rail;
a first transistor coupled between the first voltage rail and the second voltage rail;
gate drive circuitry including:
a first node coupled to a control terminal of the first transistor;
a pulse generation module having an output coupled to the first node, the pulse generation module being configured to generate a voltage pulse at the output; and
a switched capacitance arrangement coupled between the first node and a reference voltage node; and
a control module coupled to the gate drive circuitry, wherein the control module is configured to activate the switched capacitance arrangement in response to a discharge condition.

10. The electrical system of claim 9, wherein the control module is configured to provide a control signal for a duty cycle of the voltage pulse after activating the switched capacitance arrangement, the first transistor operating in a linear mode in response to the voltage pulse having the duty cycle when the switched capacitance arrangement is activated.

11. The electrical system of claim 9, wherein the control module is configured to operate the first transistor in a linear mode after activating the switched capacitance arrangement.

12. The electrical system of claim 10, further comprising a second transistor coupled between the first voltage rail and the first transistor, wherein the control module is configured to turn on the second transistor while operating the first transistor in the linear mode.

13. The electrical system of claim 12, wherein the first transistor and the second transistor comprise a phase leg of an inverter.

14. The electrical system of claim 13, further comprising an electric motor coupled to the inverter, wherein the electric motor is configured to provide traction power to a vehicle.

15. The electrical system of claim 9, wherein the gate drive circuitry includes a resistive element coupled electrically in series between the output of the pulse generation module and the first node.

16. The electrical system of claim 15, wherein:
the switched capacitance arrangement comprises:
a capacitive element; and
a second transistor coupled to the capacitive element, the capacitive element and the second transistor being configured electrically in series between the first node and the reference voltage node, the second transistor having a control terminal coupled to the control module; and
the control module is configured to activate the switched capacitance arrangement by turning on the second transistor.

17. A method for discharging an energy potential between a first node and a second node using a first transistor coupled between the first node and the second node, the method comprising:
identifying a discharge condition;
in response to identifying the discharge condition, activating a switched capacitance arrangement coupled between a reference voltage node and a third node, the third node being coupled to a control terminal of the first transistor; and
providing one or more voltage pulses to the third node after activating the switched capacitance arrangement.

18. The method of claim 17, wherein the one or more voltage pulses are configured to operate the first transistor in a linear mode.

19. The method of claim 17, further comprising turning on a second transistor coupled between the first node and the first transistor while providing the one or more voltage pulses to the third node.

20. The method of claim 19, the one or more voltage pulses being configured to operate the first transistor in a linear mode, wherein turning on the second transistor comprises operating the second transistor in a saturation mode.
